(19) United States
(12) Patent Application Publication
(10) Pub. No.: US 2010/0065467 A1
(43) Pub. Date: Mar. 18, 2010

(54) ANTIVIBRATION MECHANISM FOR ARTICLE RECEIVING CONTAINER

(75) Inventor: Masanao MURATA, MIE (JP)

Correspondence Address: DRINKER BIDDLE & REATH (DC), 1500 K STREET, N.W., SUITE 1100, WASHINGTON, DC, 20005-1209, US

(73) Assignee: Asyst Technologies Japan, Inc., Ise-Shi (JP)

(21) Appl. No.: 12/092,014

(22) PCT Filed: Oct. 31, 2006
(86) PCT No.: PCT/JP2006/321779

§ 371 Date: Sep. 11, 2009

(30) Foreign Application Priority Data
Oct. 31, 2005 (JP) 2005-316013

(51) Int. Cl. H01L 21/673; F16F 7/00; B65D 85/86

(52) U.S. Cl. 206/710; 267/141

(57) ABSTRACT

An object is to restrict vibration from being transmitted to a shelf member and thus to prevent a substrate supported on the shelf member from being damaged. An FOUP main body 3a is formed into a member separated from a shelf member 3e provided in the FOUP main body 3a, and then an elastic member 3g is interposed between the FOUP main body 3a and the shelf member 3e, thereby allowing the shelf member 3e to be elastically supported to the FOUP main body 3a.

### TECHNICAL FIELD

The present invention relates to an antivibration mechanism for an article receiving container (hereinafter, referred to as ‘Front-Opening Unified Pod: FOUP’).

In some cases, vibration may be applied to containers such as an FOUP which are transported by transport means such as a roller conveyor and a suspended elevation/transport trolley (hereinafter, referred to as Overhead Hoist Transport: OHT trolley) during a transport operation. The present invention relates to the antivibration mechanism for the article receiving container which restricts the vibration from being transmitted to articles such as a liquid crystal or multiple sheets of wafers which are received in the FOUP so as to be inserted thereto or separated therefrom.

### BACKGROUND ART

Recently, in order to perform the processes necessary for a series of treatment stations which are arranged along a circular path within a process or between processes in a clean room and perform various treatments (e.g., a thin film forming, a photolithography, a cleansing, an etching, an inspection, and the like) to the wafers, the container (FOUP) which receives the wafers therein are transported by the OHT trolley in many cases.

The treatment process of the substrate is managed by a tag attached to the FOUP which receives the substrate therein, and the contents of the tag are sequentially updated in accordance with a progress of the substrate treatment process. The substrate treatment process is specified by information of the tag attached to the FOUP, and the necessary processes since then is managed by a computer on the basis of the tag information.

In this way, an FOUP which maintains an air-tightness during the transport operation and which opens a front door to allow a robot to insert or extract the substrate one sheet by one sheet for a predetermined process of the treatment station is used upon transporting the substrates which are sequentially subjected to various treatments of the plural treatment stations one sheet by one sheet.

The configuration which has been widely used from the past is like that shown in FIG. 6. In FIG. 6, Reference Numeral 31 denotes a main body and Reference Numeral 31a denotes an opening surface. A side flange 31b, which is used when a transport operation is carried out by a human hand, is provided on both side surfaces which are positioned on both sides when viewed from the opening surface 31a. Reference Numeral 31c denotes a flange which is gripped by a finger portion of an OHT trolley described below. Accordingly, a cover member 32, which is mounted to the main body 31 and the opening surface 31a, is elevated and transported together.

Reference Numeral 31d denotes a shelf member, and an uneven shelf member is formed in the opening surface 31a so as to horizontally hold multiple sheets (for instance, 24 sheets) of substrates (wafer, liquid crystal, and the like) which are inserted and extracted by a robot which is not shown, but installed in a treatment station.

Then, the shelf member 31d is integrally fixed to the FOUP main body 31 or integrally formed with the FOUP main body 31.

In addition, the cover member 32 is maintained in an air-tight state with respect to the opening surface 31a of the FOUP main body 31 upon transporting the FOUP main body 31 and is separated from the FOUP main body 31 by unlocking a key member 32a (like the state shown in the drawing) through lock means or unlock means which is provided in the treatment station before performing a treatment of the treatment station to the received substrate.

Subsequently, when all the substrates have been subjected to the treatment of the treatment station, in the FOUP main body 31 receiving the substrates which have been subjected to the treatment, the cover member 32 closes the opening surface 31a before a transport operation, and then the key member 32a is locked by the lock means or the unlock means.

However, when the substrate such as a wafer is transported, a collision, a friction, and the like may be generated between the support member and the substrate because the substrate moves on a substrate supporting portion of a substrate transporting container, thereby causing a failure of the substrate.

For this reason, for instance, Patent Document 1 discloses a wafer carrier which is used to deliver the wafer between treatment devices and to store the wafer before being transmitted to the next process.

That is, in the wafer carrier disclosed in Patent Document 1, first, the peripheral edges of wafers 9 are inserted one sheet by one sheet into a series of groove portions 3 which are formed in an inner wall of a carrier main body 2.

Next, a tongue piece 5 which is made of flexible material presses the wafers 9 toward one side surface of the groove portions 3 so that the wafers 9 and the carrier main body 2 are appeared to be an incorporated member, thereby allowing the wafers 9 not to move in the groove portions 3.

Meanwhile, Patent Document 2 discloses a technique for preventing vibration from being transmitted to the substrate which is transported by a traveling trolley.

The technique disclosed in Patent Document 2 is particularly related to a transport operation of a substrate which becomes large in size, and is characterized in that vibration generated from a traveling trolley 7 which supports a support portion 8 in a suspended manner is restricted from being transmitted to the support portion 8 which receives a substrate 1.

That is, in order to cope with an increase in size of the substrate 1 to be transported, the substrate 1 is disposed in the support portion 8 in a longitudinal direction, and then the traveling trolley 7 and the support portion 8 are elastically supported.

As specific means for this technique, an antivibration mechanism 22 is provided to absorb vibration in three-dimensional three directions, that is, a vertical direction, a traveling direction, and a direction perpendicular to the traveling direction in the traveling trolley.

### Patent Document 1: Japanese Patent No. 3212890

### Patent Document 2: Japanese Patent Publication No. 2004-359436A

### DISCLOSURE OF THE INVENTION

### Problems to be Solved by the Invention

In the past, for instance, the FOUP shown in FIG. 6 was used when transporting the substrates such as the wafers which are subjected to various treatments of the treatment stations one sheet by one sheet.

In the FOUP, since a main body 31 and a shelf member 31d are fixed in a predetermined arrangement, vibration applied to the FOUP main body 31 during a transport operation is directly transmitted to the shelf member 31d.

Accordingly, the vibration transmitted to the FOUP main body 31 during the transport operation is directly transmitted to multiple sheets of wafers which are placed on the shelf member 31d in horizontal posture so as to be inserted thereto or extracted therefrom one sheet by one sheet.

The vibration corresponds to vibration due to inertia generated upon accelerating or decelerating the FOUP main body and slight vibration generated from the driving portion, and the occurrence cannot be avoided.

The vibration which is applied to the shelf member 31d in this way causes the substrate to protrude from a substrate placement surface of the shelf member 31d or generates friction between the substrate placement surface and the substrate, and thus a problem arises in that a failure of the substrate occurs.

In an FOUP which is transported by driving means such as an OHT trolley and which includes a shelf member for holding multiple sheets of substrates such as wafers in a horizontal posture so as to be inserted thereto or extracted therefrom one sheet by one sheet, while the container is transported, the FOUP is applied with vibration due to inertia generated during an acceleration or a deceleration and slight vibration transmitted from a driving source. Therefore, an object of the invention is to provide a technique for allowing the container to elastically support the shelf member in order to restrict such vibration from being transmitted to the shelf member to thereby prevent a damage from occurring in all articles including the substrates such as the wafers supported on the shelf member.

### Means for Solving the Problem

In order to solve the above-described problems, Aspect 1 of the invention provides an antivibration mechanism for an article receiving container including: an article receiving container which is transported by transport means traveling along a predetermined path and has a shelf member supporting an article to be transported; and an elastic member which restricts vibration applied to the article receiving container upon operating the transport means from being transmitted to the shelf member, wherein the elastic member is disposed at a proper position in which the article receiving container supports the shelf member so that the article receiving container supports the shelf member through the elastic member.

According to the invention described in Aspect 1, even when the container which holds the shelf member therein is applied with all vibration generated from transport means other than the OHT, the shelf member which places the article to be transported thereon does not directly receive all vibration, but receives the vibration in a restricted state.

Accordingly, it is possible to safely transport the article to be transported without damaging the article to be transported just by regulating the article to be transported without a damage in such a manner that the specification of the elastic member which elastically supports the shelf member to the container and restricts vibration from being transmitted from the container to the shelf member is appropriately adjusted.

In addition, it is possible to easily realize the invention because the antivibration means easily matches with a transport machine which is manufactured based on the specification of the current FOUP in that the antivibration means which is applied to the container in order to restrict vibration from being transmitted from the transport means to the article to be transported is simple.

Aspect 2 of the invention provides the antivibration mechanism for the article receiving container according to Aspect 1, wherein the article to be transported is a wafer, wherein the shelf member is a member which holds the wafer so as to be inserted or extracted in a horizontal direction, and wherein the article receiving container which receives the shelf member is an FOUP.

According to the invention described in Aspect 2, of course, in addition to the advantage according to Aspect 1, in the case that the wafers can be damaged if vibration transmitted from the transport means to the FOUP is directly transmitted to the wafers, it is possible to accurately prevent vibration causing a failure from being transmitted to the wafers which are placed on the shelf member of the FOUP so as to be inserted thereto or extracted therefrom.

Aspect 3 of the invention provides the antivibration mechanism for the article receiving container according to Aspect 1, wherein a plurality of protrusions are formed in upper and lower end surfaces of the shelf member, wherein holes with a size that the protrusions can be loosely fitted are formed in predetermined positions of upper and lower surfaces of the article receiving container, and wherein the protrusions are supported to the corresponding holes through the elastic member.

According to the invention described in Aspect 3, of course, in addition to the advantage according to Aspect 1 or Aspect 2, since a relative relation between the protrusions provided on the shelf member and the holes provided in the container is regulated, it is possible to accurately carry out a positioning operation in which the shelf member is positioned to the container such as the FOUP. Further, it is possible to obtain required antivibration effect by selecting the material and the size of the elastic member which is disposed between the holes and the protrusions.

Aspect 4 of the invention provides the antivibration mechanism for the article receiving container according to Aspect 1, wherein the elastic member is interposed between the upper and lower end surfaces so that the shelf member is elastically supported to the article receiving container.

According to the invention described in Aspect 4, of course, in addition to the advantage according to Aspect 1 or Aspect 2, it is possible to accurately prevent a failure from occurring in the articles to be transported such as the wafers with a simple configuration in which the elastic member is interposed between the upper and lower ends of a general shelf member and the upper and lower ends of the container corresponding to the shelf member so as to obtain required antivibration function.

Aspect 5 of the invention provides the antivibration mechanism for the article receiving container according to Aspect 4, wherein the elastic member is a plate spring.

According to the invention described in Aspect 5, of course, in addition to the advantage according to Aspect 4, it is possible to reduce the number of processes necessary for fixing the shelf member to the container.

Aspect 6 of the invention provides the antivibration mechanism for the article receiving container according to Aspect 1, wherein the transport means is an overhead hoist transport unit which travels along a circular path within a process or between processes.

According to the invention described in Aspect 6, of course, in addition to the advantage according to Aspect 1, particularly, it is possible to restrict vibration from being transmitted to the articles transported by the OHT trolley. When a transport speed becomes high, inertia generated upon starting or stopping the OHT trolley tends to increase, thereby increasing vibration. In addition, since the driving portion and the container such as the FOUP can be attached to or detached from the OHT trolley, it is not possible to interpose a vibration absorbing member between them. However, according to the invention described in Aspect 6, it is possible to restrict vibration from being transmitted to the articles which are transported by the OHT trolley.

Aspect 7 of the invention provides an article receiving container which is transported by transport means traveling along a predetermined path, the article receiving container including: a shelf member which supports an article to be transported; and an elastic member which restricts vibration applied to the article receiving container upon operating the transport means from being transmitted to the shelf member, wherein the elastic member is disposed at a proper position in which the article receiving container supports the shelf member so that the article receiving container supports the shelf member through the elastic member.

According to the invention described in Aspect 7, even when the container which holds the shelf member therein is applied with all vibration generated from transport means other than the OHT, the shelf member which places the article to be transported thereon does not directly receive all vibration, but receives the vibration in a restricted state.

Accordingly, it is possible to safely transport the article to be transported without damaging the article to be transported just by regulating the article to be transported without a damage in such a manner that the specification of the elastic member which elastically supports the shelf member to the container and restricts vibration from being transmitted from the container to the shelf member is appropriately adjusted.

In addition, it is possible to easily realize the invention because the antivibration means easily matches with a transport machine which is manufactured based on the specification of the current FOUP in that the antivibration means which is applied to the container in order to restrict vibration from being transmitted from the transport means to the article to be transported is simple.

Although the wafer carrier disclosed in Patent Document 1 can prevent collision or friction between the wafer and the support surface thereof upon being applied with all vibration while transporting the wafer, it is difficult to apply the wafer carrier to the present invention.

That is, the present invention has a basic configuration in which the shelf member is installed in the container such as the FOUP so that multiple sheets of substrates (other than wafers) are received in the shelf member so as to be inserted thereto or extracted therefrom. Then, the invention is used in a different way from the technique disclosed in Patent Document 1 in which multiple sheets of wafers are disposed in the longitudinal direction so as not to move on the respective support surfaces and the wafers are extracted from the container when the wafers are not transported.

In order to apply the technique disclosed in Patent Document 1 to the present invention, since a maintaining/opening mechanism for the wafer needs to be prepared, the container necessarily becomes large in size or the mechanism becomes complicated. Further, the invention mismatches with the transport machine which is manufactured on the basis of the specification of the current FOUP, and thus it is difficult to put to practical use.

Meanwhile, the transport device disclosed in Patent Document 2 allows multiple sheets of materials (substrates) 1 to be received in a material (substrate) supporting portion 8 in the longitudinal direction and includes an antivibration mechanism 22 which is disposed between a traveling trolley 7 and the material (substrate) supporting portion 8 so as to absorb vibration in three directions, that is, a front/rear direction, a left/right direction, and a up/down direction with respect to the traveling direction of the traveling trolley 7.

With such a configuration, since the antivibration mechanism 22 accurately restricts all vibration in the followings (A) to (C) generated while the traveling trolley 7 travels from being transmitted to the material (substrate) which is transported while being received in the material (substrate) supporting portion 8, it is possible to prevent a damage from occurring in the substrate due to vibration applied to the substrate.

(A) slight vibration generated from the driving portion of the traveling trolley 7

(B) vibration generated from inertia occurring upon accelerating or decelerating the traveling trolley 7

(C) vibration generated from wind pressure in accompany with a traveling operation of the traveling trolley 7

Certainly, the technique disclosed in Patent Document 2 restricts all vibration generated from the transport trolley 7 of the transport device while the transport device transports the substrate from being transmitted to the substrate 1 to be transported, thereby preventing a damage caused by vibration from occurring in the substrate 1.

However, in the technique disclosed in Patent Document 2, the transport trolley 7 with a driving source is connected to the material (substrate) supporting portion 8 for supporting the material (substrate) 1 through the antivibration mechanism 22 so that the connection state cannot be released.

Accordingly, multiple sheets of materials (substrates) 1 are collected and mounted to the material (substrate) supporting portion 8 in a predetermined position, and then are extracted from the material (substrate) supporting portion 8 of the transport trolley 7 in a different predetermined position. As a result, it is not possible to apply the technique to the invention with a basic configuration in which the substrates are inserted or extracted one sheet by one sheet.

### BRIEF DESCRIPTION OF THE DRAWINGS

FIG. 1 is a side view illustrating a relationship between an FOUP and an OHT trolley for transporting the FOUP according to Embodiment 1 of the invention.

FIG. 2 is a perspective view illustrating an internal configuration of an FOUP main body according to Embodiment 1 of the invention.

FIG. 3 is a sectional view illustrating a configuration of a main part of the FOUP according to Embodiment 1 of the invention.

FIG. 4 is a schematic view illustrating a configuration of a main part according to Embodiment 2 of the invention.

FIG. 5 is a schematic view illustrating a configuration of a main part according to Embodiment 3 of the invention.

FIG. 6 is a perspective view illustrating the FOUP commonly used in the invention.

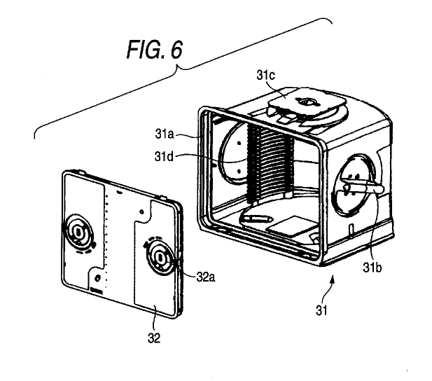

### DESCRIPTION OF REFERENCE NUMERALS AND SIGNS

2: OHT TROLLEY

3, 13, 23: FOUP

3e, 13e, 23e: SHELF MEMBER

3ex, 13ex, 23ex: SHELF

3ey: PROTRUSION

3g, 13g: ELASTIC MEMBER

23g: PLATE SPRING

### BEST MODE FOR CARRYING OUT THE INVENTION

### Embodiment 1

Hereinafter, an exemplary embodiment of the invention will be described with reference to the accompanying drawings.

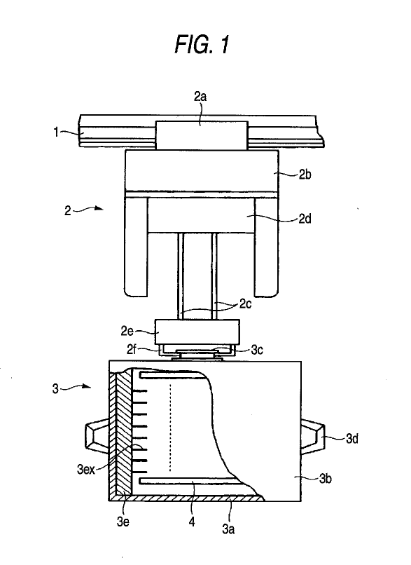

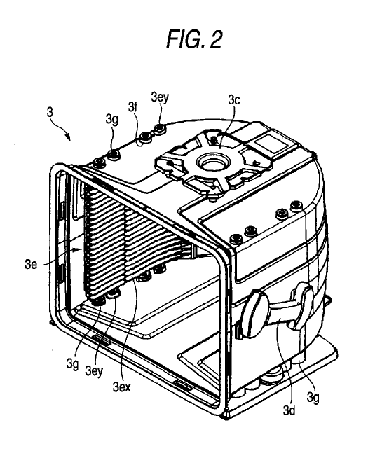

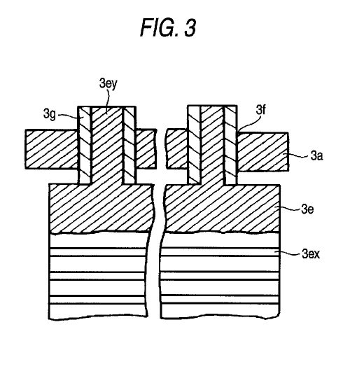

First, an outline of the drawings according to the embodiment will be described. FIG. 1 is a side view illustrating a relationship between a FOUP according to the invention and an OHT trolley for transporting the FOUP. FIG. 2 is a perspective view illustrating an internal configuration of an FOUP main body portion according to the invention. FIG. 3 is a sectional view illustrating a configuration of a main part of the FOUP according to the invention.

Next, a relationship between the FOUP according to the invention and the OHT trolley as means for transporting the FOUP will be described with reference to FIG. 1.

FIG. 1 illustrates a part of a circular path of an OHT trolley 2 within a process or between processes, and Reference Numeral 1 denotes a traveling rail. The OHT trolley 2 travels in such a manner that a traveling wheel and a guiding wheel of a guide/drive portion 2a are regulated in the traveling rail 1.

At this time, a necessary motive power can be obtained by the general means in which the traveling wheel is provided with a driving motor or the rail 1 and the OHT trolley 2 are respectively provided with a secondary linear motor and a primary linear motor constituting a DC linear motor.

Reference Numeral 2b denotes a positioning mechanism which adjusts a variation in the rotation direction and the direction perpendicular to the direction in which the OHT trolley travels in the traveling rail 1 of the container (FOUP) described below. Reference Numeral 2c denotes a band-shaped belt, and four band-shaped belts are provided at positions of front/rear and left and right in the traveling direction of the OHT trolley 2 so as to be elastically controlled by an elevation mechanism 2d provided in the OHT trolley 2, thereby elevating an elevation member 2e. Then, the band-shaped belt 2c has an electrical wire (not shown) which is disposed therein so as to supply an electrical power to the elevation member 2e and to send and receive a control signal to and from the elevation member.

Reference Numeral 2f denotes a gripper member which corresponds to one of components constituting the elevation member 2e, and the gripper member supported so as to be movable in the left/right direction in the drawing. Reference Numeral 3 denotes the FOUP as an article to be transported including a main body member 3a, a cover member 3b, a flange 3c which is gripped or released by the operation of the gripper member 2f, a side flange 3d which is used for transport means by a human hand, and a shelf member 3e on which multiple sheets of wafers 4 are placed so as to be inserted through a main body opening. At this time, a series of shelves 3ex are arranged in the shelf member 3e in the vertical direction so as to place one sheet of wafer thereon without a case that the wafers 4 contact with each other.

Next, a configuration in which vibration is restricted from being transmitted to the shelf member 3e when the shelf member 3e is elastically supported to the inside of the FOUP 3 and the FOUP 3 is controlled to be transported or elevated by the OHT trolley 2 will be described with reference to FIGS. 2 and 3.

Additionally, in FIGS. 2 and 3, the same reference numerals are given to the components corresponding to that shown in FIG. 1, and the repetitive description will be omitted.

The configuration shown in FIG. 2 is that the internal mechanism of the FOUP 3 is also shown in a state that the cover member 3b (see FIG. 1) is separated. Reference Numeral 3f denotes a series of holes which are formed in the upper and lower portions of the FOUP in which the upper and lower ends of the shelf member 3e are opposed to each other.

By referring to FIG. 3, Reference Numeral 3ey denotes a protrusion which is provided at positions opposed to the series of holes 3f so as to extend from the upper and lower end surfaces of the shelf member 3e. At this time, the protrusion has a thickness which can be loosely fitted to the corresponding hole.

Reference Numeral 3g denotes a ring-shaped elastic member which is air-tightly filled in a gap, which is generated when the series of holes 3f and the corresponding protrusions 3ey are loosely fitted to each other, with a uniform a surrounding thickness.

In addition, although the ring-shaped elastic members 3g can be filled in the series of holes at any time before and after the assembling operation of the FOUP 3, the fitting operation in which the protrusions 3ey are fitted to the series of holes 3f needs to be carried out before the assembling operation of the FOUP 3.

Then, a degree how much the ring-shaped elastic member 3g prevents vibration from being transmitted is determined in such a manner that a thickness of the ring-shaped elastic member 3g, that is, a length corresponding to an average gap between the protrusion 3g and the corresponding hole 3f and an elastic coefficient of the material of the ring-shaped elastic member 3g are appropriately selected.

The degree how much the ring-shaped elastic member 3g prevents vibration from being transmitted is determined in consideration of the transport means (e.g., an OHT trolley 2, a roller conveyor, and the like) of the FOUP 3 which does not damage the wafer 4 placed on the shelf 3ex of the shelf member 3e. However, it is not a good counter measure to increase a cost by restricting vibration from being transmitted more than its required value.

In addition, a filling material such as an adhesive may be coated on the inner and outer surfaces of the ring-shaped elastic member 3g in accordance with the necessity of air-tightness.

Next, an effect according to the embodiment will be described with reference to FIGS. 1 and 2.

First, for instance, wafers 4 which are not processed in a stocker (not shown) are placed sequentially one sheet by one sheet on the series of the shelves 3ex of the shelf member 3e which is installed therein, and then the FOUP 3 in which the cover member 3b locks the opening of the main body 3a is in a standby state so as to be transported to a predetermined treatment station (not shown).

Next, the elevation member 2e is elevated down to a position just above the FOUP 3 by unwinding the band-shaped belt 2c of the OHT trolley 2 which is traveled up to a position of the FOUP 3 which is in the standby state to thereby allow the gripper member 2f to grip the flange 3c of the FOUP 3.

Subsequently, the band-shaped belt 2c is wound in a state that the gripper member 2f keeps gripping the flange 3c of the FOUP 3. The FOUP 3 moves to the inside of the OHT trolley 2, and then travels to a predetermined treatment station.

In the treatment station (not shown), the band-shaped belt 2c is unwound, the gripper member 2f releases the lock of the flange 3c of the FOUP 3, and then the OHT trolley 2 moves to transport an additional FOUP.

In the FOUP 3 which is transported to the treatment station to thereby release the engagement of the flange 3c, the cover member 3b is unlocked, a predetermined process is performed to the wafers 4 which are placed sequentially one sheet by one sheet on the series of shelves 3ex which are arranged in the vertical direction, and then the wafers 4 which have been subjected to the predetermined process are again returned to the predetermined shelves 3ex.

When all the wafers 4 have been subjected to the predetermined process to be thereby returned to the shelves 3ex in this way, the cover member 3b is locked, and then the FOUP 3 is again transported to an additional treatment station or the stocker by the OHT trolley in the same way as described above.

Incidentally, the wafers are placed on the series of shelves 3ex just because it is necessary to place the wafers 4 which are sequentially subjected to different processes in the various stations on the series of the shelves 3ex of the shelf member 3e so as to be inserted thereto or separated therefrom.

For this reason, if all vibration generated from the OHT trolley 2, that is, vibration transmitted to the FOUP 3 in accompany with inertia generated upon accelerating or decelerating a traveling/elevating operation during particularly a high-speed transporting process is directly transmitted to the shelf member 3e, the wafers 4 which are placed on the shelves 3ex of the shelf member 3e undergo a protruding shock or a friction generated on the shelves 3ex. At this time, when a degree of the protruding shock or the friction exceeds a limitation, the wafers 4 are damaged to thereby cause a failure thereof.

However, although it is difficult to prevent vibration by 100% when the FOUP 3 is influenced by the OHT trolley during the traveling/elevating operation, since the shelf member 3e is supported to the FOUP main body 3a through the ring-shaped elastic member 3g as shown in FIG. 2, it is possible to restrict vibration from damaging the wafers 4 by selecting the size, the material, and the like of the ring-shaped elastic member 3 depending on the expected vibration to be applied to the FOUP 3.

### Embodiment 2

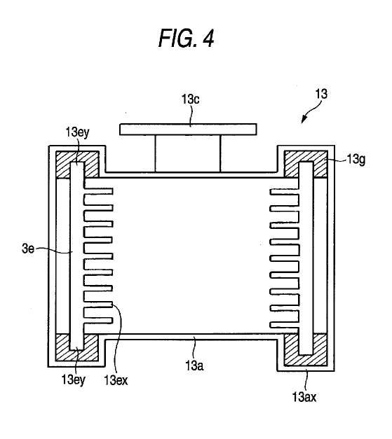

FIG. 4 is a schematic view illustrating a main part according to Embodiment 2 which is a modified example of the above-described embodiment. In FIG. 4, an FOUP 13 basically includes an FOUP main body 13a, a flange 13c, and a shelf member 13e.

Then, a characteristic configuration of Embodiment 2 is support means for supporting the shelf member 13e to the FOUP main body 13a.

Specifically describing the support means, upper and lower ends 13ey without shelves 13ex of the shelf member 13e are held by elastic members 13g.

In addition, the elastic members 13g are fixed to support portions 13ax which are formed in positions corresponding to the upper and lower ends 13ey of the shelf member 13e.

With the configuration shown in FIG. 4, when the FOUP 13 is applied with all vibration from other transport means other than the OHT trolley through the flange 13c, all vibration is attenuated by the elastic members 13g at a ratio in accordance with the characteristic of the elastic members 13g.

Accordingly, in principle, although it is not possible to completely remove the vibration transmitted to the wafers (see Reference Numeral 4 shown in FIG. 1) which are placed on the shelves 13ex of the shelf member 13e so as to be inserted thereto or separated therefrom, it is possible to restrict the vibration from being transmitted to the wafers to thereby cause a failure thereof by appropriately selecting the elastic members 13g.

### Embodiment 3

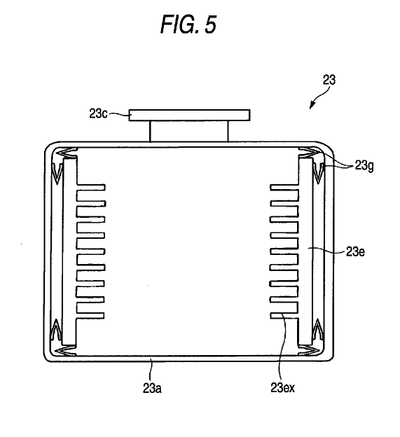

FIG. 5 is a schematic view illustrating a main part according to Embodiment 3 which is a modified example of the above-described embodiment. In FIG. 5, an FOUP 23 basically includes an FOUP main body 23a, a flange 23c, and a shelf member 23e.

Then, a characteristic configuration of the embodiment 3 is support means for supporting the shelf member 23e to the FOUP main body 23a. Specifically describing the support means, a plate spring 23g is disposed in the vicinity of the upper and lower ends of the shelf member 23e, and both ends of the plate spring 23g are respectively connected to the shelf member 23e and the inner circumferential surface of the FOUP main body 23a.

In such a configuration, since the shelf member 23e is elastically supported to the FOUP main body 13a through the plate springs 23g, vibration applied through the flange 23c when the FOUP main body 23a is applied with a traveling/elevating action from other transport means other than the OHT trolley is restricted by vibration restricting effect in accordance with the elastic characteristic of the plate spring 23g to be thereby transmitted to the shelf member 23e.

Accordingly, in principle, although it is not possible to completely remove the vibration transmitted to the wafers (see Reference Numeral 4 shown in FIG. 1) which are placed on the shelves 23ex of the shelf member 23e so as to be inserted thereto or separated therefrom, it is possible to restrict the vibration from being transmitted to the wafers to thereby cause a failure thereof by appropriately selecting the elastic members 23g.

In addition, the invention is applicable to other transport containers such as a reticle transporting container and a liquid crystal substrate transporting container which require a counter measure for vibration other than the semiconductor substrate receiving container.

While the invention has been described in detail with reference to the specific embodiment, it should be understood, of course, that various modifications or corrections may be readily made by those skilled in the art without departing from the spirit and the scope of the invention.

This application claims the benefit of Japanese Patent application No. 2005-316013 filed Oct. 31, 2005, the entire contents of which are incorporated herein by reference.

### INDUSTRIAL APPLICABILITY

According to the antivibration mechanism for the article receiving container, even when the container which holds the shelf member therein is applied with all vibration generated from transport means other than the OHT, the shelf member which places the article to be transported thereon does not directly receive all vibration, but receives the vibration in a restricted state.

Accordingly, it is possible to safely transport the article to be transported without damaging the article to be transported just by regulating the article to be transported without a damage in such a manner that the specification of the elastic member which elastically supports the shelf member to the container and restricts vibration from being transmitted from the container to the shelf member is appropriately adjusted.

In addition, it is possible to easily realize the invention because the antivibration means easily matches with a prior machine which is manufactured based on the specification of the current FOUP in that the antivibration means which is applied to the container in order to restrict vibration from being transmitted from the transport means to the article to be transported is simple.

1. An antivibration mechanism for an article receiving container comprising:
an article receiving container which is transported by transport means traveling along a predetermined path and has a shelf member supporting an article to be transported; and
an elastic member which restricts vibration applied to the article receiving container upon operating the transport means from being transmitted to the shelf member,
wherein the elastic member is disposed at a proper position in which the article receiving container supports the shelf member so that the article receiving container supports the shelf member through the elastic member.

2. The antivibration mechanism for the article receiving container according to claim 1, wherein the article to be transported is a wafer,
wherein the shelf member is a member which holds the wafer so as to be inserted or extracted in a horizontal direction, and
wherein the article receiving container which receives the shelf member is an FOUP.

3. The antivibration mechanism for the article receiving container according to claim 1, wherein a plurality of protrusions are formed in upper and lower end surfaces of the shelf member,
wherein holes with a size that the protrusions can be loosely fitted are formed in predetermined positions of upper and lower surfaces of the article receiving container, and
wherein the protrusions are supported to the corresponding holes through the elastic member.

4. The antivibration mechanism for the article receiving container according to claim 1, wherein the elastic member is interposed between the upper and lower end surfaces so that the shelf member is elastically supported to the article receiving container.

5. The antivibration mechanism for the article receiving container according to claim 4, wherein the elastic member is a plate spring.

6. The antivibration mechanism for the article receiving container according to claim 1, wherein the transport means is an overhead hoist transport unit which travels along a circular path within a process or between processes.

7. An article receiving container which is transported by transport means traveling along a predetermined path, the article receiving container comprising:
a shelf member which supports an article to be transported; and
an elastic member which restricts vibration applied to the article receiving container upon operating the transport means from being transmitted to the shelf member,
wherein the elastic member is disposed at a proper position in which the article receiving container supports the shelf member so that the article receiving container supports the shelf member through the elastic member.
